(19) United States
(12) Patent Application Publication
(10) Pub. No.: US 2025/0150038 A1
(43) Pub. Date: May 8, 2025

(54) CLASS-D AUDIO AMPLIFIER AND NOISE ELIMINATION DEVICE THEREOF

(71) Applicant: Elite Semiconductor Microelectronics Technology Inc., Hsinchu City (TW)

(72) Inventors: Hsin-Yuan Chiu, Hsinchu City (TW); Hsiang-Yu Yang, Hsinchu City (TW); Tien-I Yang, Hsinchu City (TW)

(21) Appl. No.: 18/387,091

(22) Filed: Nov. 6, 2023

(51) Int. Cl. H03F 1/26; H03F 3/217

(52) U.S. Cl. CPC H03F 1/26; H03F 3/217; H03F 2200/03; H03F 2200/331

(57) ABSTRACT

A noise elimination device for a Class-D audio amplifier includes a residual signal detector and a multiplexer, wherein the multiplexer is electrically connected with a sigma-delta modulator (SDM) and a pulse width modulator (PWM) of the Class-D audio amplifier and the residual signal detector. The residual signal detector is configured to detect whether an input signal of the Class-D audio amplifier is residual. The multiplexer is configured to output zero data into the pulse width modulator when the residual signal detector detects that the input signal of the Class-D audio amplifier is residual.

### BACKGROUND OF THE INVENTION

The disclosure relates to a Class-D audio amplifier. More specifically, the disclosure relates to a Class-D audio amplifier and a noise elimination device for the same, which can detect whether there is a residual signal in the Class-D audio amplifier and eliminate noise caused by the residual signal.

Class-D audio amplifiers usually adopt a sigma-delta modulator (SDM) to implement a digital-to-analog conversion or an analog-to-digital conversion for an audio signal, and adopt a pulse width modulator (PWM) to provide a power stage with a series of pulses having different widths. Generally, the SDM includes a feedback circuit, which may cause a residual signal in a Class-D audio amplifier even if the audio input signal of the Class-D audio amplifier has been turned off. Once the residual signal is outputted into the PWM and then into the power stage, the output of the Class-D audio amplifier includes additional noise. In view of this, it is important to overcome the problem in the art.

### SUMMARY OF THE INVENTION

To overcome at least the aforesaid problem, the present disclosure provides a noise elimination device for a Class-D audio amplifier. The noise elimination device may include a residual signal detector and a multiplexer. The multiplexer is electrically connected with a sigma-delta modulator (SDM) and a pulse width modulator (PWM) of the Class-D audio amplifier and the residual signal detector. The residual signal detector may be configured to detect whether an input signal of the Class-D audio amplifier is residual. The multiplexer may be configured to output zero data into the pulse width modulator when the residual signal detector detects that the input signal of the Class-D audio amplifier is residual.

To overcome at least the aforesaid problem, the present disclosure also provides a Class-D audio amplifier. The Class-D audio amplifier may include a sigma-delta modulator (SDM), a pulse width modulator (PWM), and a noise elimination device. The noise elimination device may include a residual signal detector and a multiplexer. The multiplexer is electrically connected with the sigma-delta modulator, the pulse width modulator (PWM) and the residual signal detector. The residual signal detector may be configured to detect whether an input signal of the Class-D audio amplifier is residual. The multiplexer may be configured to output zero data into the pulse width modulator when the residual signal detector detects that the input signal of the Class-D audio amplifier is residual.

The proposed noise elimination device is able to detect whether an input signal of the Class-D audio amplifier is residual and remove the residual signal from the Class-D audio amplifier by forcibly inputting zero data into the pulse width modulator when it detects that the input signal of the Class-D audio amplifier is residual, thereby eliminating or reducing the output noise of the Class-D audio amplifier caused by the residual signal.

The summary is not intended to limit the claimed invention, but merely provides basic profile of the claimed invention. The details of the claimed invention will be described with various embodiments as presented below.

### BRIEF DESCRIPTION OF DRAWINGS

FIG. 1 illustrates a schematic view of a Class-D audio amplifier including a noise elimination device according to some embodiments of the present disclosure.

FIG. 2A provides a waveform diagram of an input signal of the Class-D audio amplifier with only one threshold for showing how the noise elimination device detects whether the input signal is residual.

FIG. 2B provides a waveform diagram of an input signal of the Class-D audio amplifier with two thresholds for showing how the noise elimination device detects whether the input signal is residual.

### DETAILED DESCRIPTION OF THE INVENTION

The embodiments as disclosed below are not intended to limit the claimed invention to any specific environment, applications, structures, processes or situations. In the attached drawings, elements which are not directly related to the claimed invention are omitted from depiction. Dimensions and dimensional relationships among individual elements in the attached drawings are only exemplary examples and are not intended to limit the claimed invention. Unless stated particularly, same element numerals may correspond to same elements in the following description without inconsistency with the claimed invention.

The terminology used herein is for the purpose of describing the embodiments only and is not intended to limit the claimed invention. The singular forms “a” and “an” are intended to include the plural forms as well, unless the context clearly indicates otherwise. The terms “comprises,” “comprising,” “includes,” “including,” etc., specify the presence of the stated features, integers, operations, elements, and/or components, but do not preclude the presence or addition of one or more other features, integers, operations, elements, components, and/or groups thereof. The term “and/or” includes any and all combinations of one or more of the associated listed items. Although the terms “first,” “second,” etc., may be used herein to describe various elements, these elements should not be limited by these terms. These terms are merely used to distinguish one element from another element. Thus, for example, a first element described below could also be termed a second element, without departing from the spirit and scope of the claimed invention.

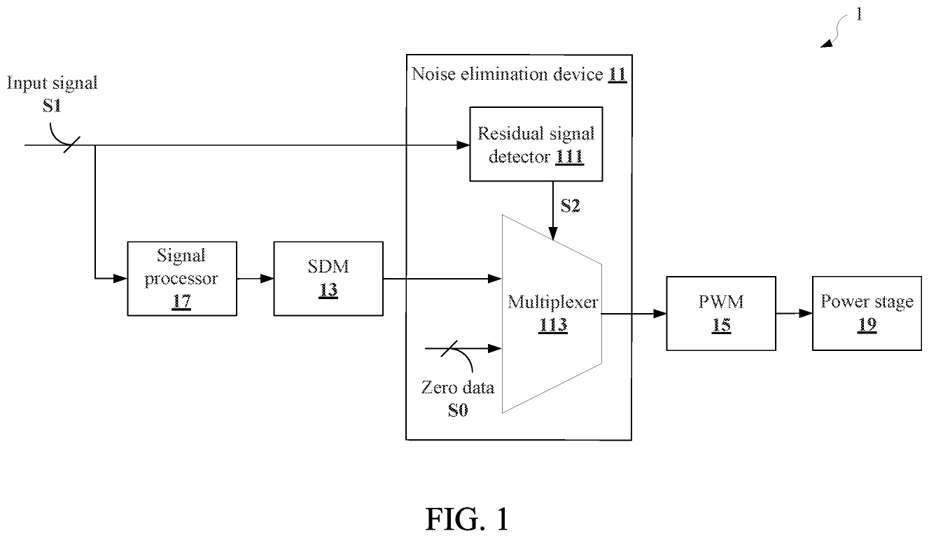

FIG. 1 illustrates a schematic view of a Class-D audio amplifier including a noise elimination device according to some embodiments of the present disclosure. The contents shown in FIG. 1 are provided only for illustrating embodiments of the present disclosure and should not be construed as any limitations on the claimed invention.

Referring to FIG. 1, there is a Class-D audio amplifier 1 including a noise elimination device 11. The Class-D audio amplifier 1 may be an open-loop Class-D audio amplifier and may basically include, for example, a sigma-delta modulator (SDM) 13, a pulse width modulator (PWM) 15, a power stage 19 and a signal processor 17. The signal processor 17 is optional, depending on design needs. The sigma-delta modulator 13, pulse width modulator 15, the power stage 19 and the signal processor 17 are electrically connected directly or indirectly.

The optional signal processor 17 may be configured to perform various signal processes to an input signal S1 (an audio signal) of the Class-D audio amplifier 1 to convert it into one with a proper signal form for an input of the sigma-delta modulator 13. For example, when the input signal S1 is an analog signal, the signal processor 17 may perform an analog-to-digital conversion and a digital signal process in order to convert the input signal S1 into a digital signal with proper signal form which is necessary for the input of the sigma-delta modulator 13. Alternatively, when the input signal S1 is a digital signal, the signal processor 17 may perform a digital signal process to enable the input signal S1 to meet the signal form which is necessary for the input of the sigma-delta modulator 13.

The sigma-delta modulator 13 may be configured to perform a digital-to-analog conversion or an analog-to-digital conversion for audio input signals. Taking a digital system as an example, the sigma-delta modulator 13 may convert a digital input signal S1 into an PCM signal such that the pulse width modulator 15 may modulate the PCM signal to generate a series of pulses with different pulse widths. Then, the power stage 19 may amplify the series of pulses to generate a driving signal for a speaker (not shown). The sigma-delta modulator 13 includes a feedback circuit, which may cause a residual signal in the Class-D audio amplifier 1 even if the audio input signal S1 of the Class-D audio amplifier1 has been turned off. As mentioned below, the bad effect caused by the residual signal can be reduced by the proposed noise elimination device 11.

The noise elimination device 11 may include a residual signal detector 111 and a multiplexer 113 which is electrically connected with the sigma-delta modulator 13, the pulse width modulator 15 and the residual signal detector 111. The multiplexer 113 may include two input terminals and one output terminal, and one of the input terminals is configured to receive an output of the sigma-delta modulator 13 and the other is configured to receive zero data S0. In addition, the output terminal of the multiplexer 113 is configured to output either the signal from the output of the sigma-delta modulator 13 or zero data, depending on a selection signal S2 which is generated by the residual signal detector 111 in response to its detection results. More specifically, the residual signal detector 111 may be configured to detect whether an input signal S1 (an audio signal) of the Class-D audio amplifier 1 is residual, and in order to reduce the bad effect of residual signals, the multiplexer 113 may be configured to forcibly output the zero data S0 into the pulse width modulator 15 when the residual signal detector 111 detects that the input signal S1 is residual. In the case where the zero data S0 is outputted into the pulse width modulator 15, the power stage 19 may thus generate a driving signal with less noise for the speaker (not shown).

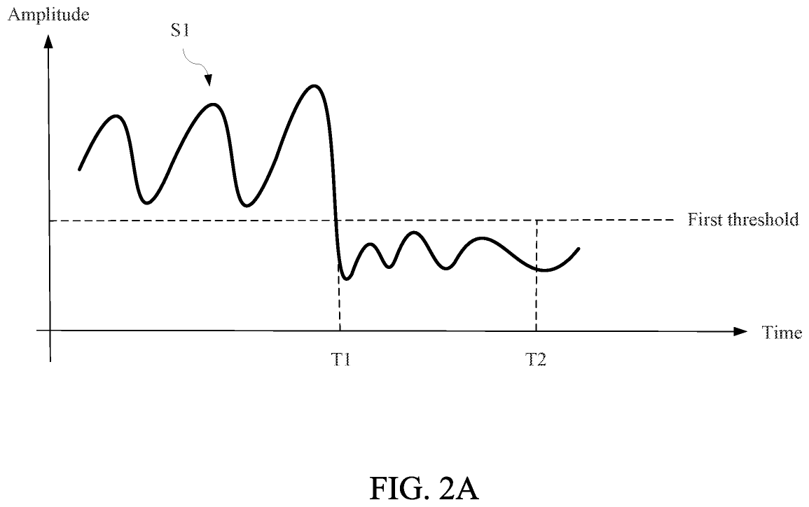

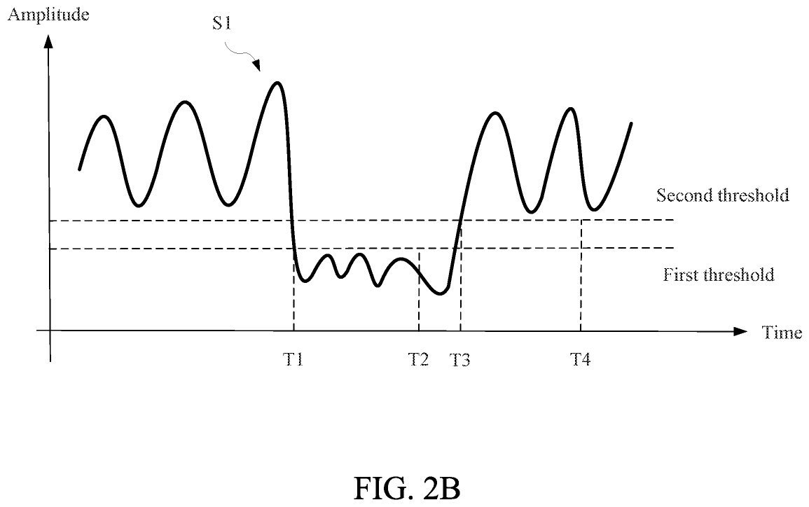

In some embodiments, there may be only one threshold (named “first threshold”) set for the residual signal detector 111, as shown in FIG. 2A. FIG. 2A provides a waveform diagram of the input signal S1 with only one threshold (the first threshold) for showing how the residual signal detector 111 detects whether the input signal S1 is residual. The contents shown in FIG. 2A are only provided for illustrating embodiments of the present disclosure and should not be construed as any limitations on the claimed invention. In these embodiments, the residual signal detector 111 may detect that the input signal S1 of the Class-D audio amplifier 1 is residual at the time point T1 where an amplitude of the input signal S1 of the Class-D audio amplifier 1 is just lower than the first threshold. In contrast, the residual signal detector 111 may not detect that the input signal S1 of the Class-D audio amplifier 1 is residual as long as the amplitude of the input signal S1 of the Class-D audio amplifier 1 is not lower than the first threshold.

Alternatively, the residual signal detector 111 may detect that the input signal S1 of the Class-D audio amplifier 1 is residual at the time point T2 where the amplitude of the input signal S1 of the Class-D audio amplifier 1 has been lower than the first threshold for a predetermined first period of time. In this case, the residual signal detector 111 may not detect that the input signal S1 of the Class-D audio amplifier 1 is residual as long as the amplitude of the input signal S1 of the Class-D audio amplifier 1 is not lower than the first threshold for the predetermined first period of time.

In some embodiments, there may be two thresholds (named “first threshold” and “second threshold”) set for the residual signal detector 111, as shown in FIG. 2B. FIG. 2B provides a waveform diagram of the input signal S1 with two thresholds (the first threshold and the second threshold) for showing how the residual signal detector 111 detects whether the input signal S1 is residual. The contents shown in FIG. 2B are only provided for illustrating embodiments of the present disclosure and should not be construed as any limitations on the claimed invention. The second threshold is higher than the first threshold. The first threshold shown in FIG. 2B is the same as shown in FIG. 2A; that is the residual signal detector 111 may detect that the input signal S1 of the Class-D audio amplifier 1 is residual at the time point T1 to T2 as mentioned above for FIG. 2A. The difference is that the residual signal detector 111 may detect that the input signal S1 of the Class-D audio amplifier 1 is a normal audio signal at the time point T3 where the amplitude of the input signal S1 of the Class-D audio amplifier 1 is just higher than the second threshold. Alternatively, the residual signal detector 111 may detect that the input signal S1 of the Class-D audio amplifier 1 is a normal audio signal at the time point T4 where the amplitude of the input signal S1 of the Class-D audio amplifier 1 has been higher than the second threshold for a predetermined second period of time. The predetermined first and second periods of time may be different or the same, depending on design needs.

In some embodiments, the residual signal detector 111 may include a counter configured to determine the time points T1-T4 and the predetermined first and second periods of time.

The first and second thresholds may be predetermined. For example, in a case where a power supply with 24 Volt is provided for a load with 8 Ohm, the first threshold may range from −90 dB to −110 dB with a preference for −110 dB, and the second threshold may range from −80 dB to −100 dB with a preference for −100 dB.

Without inconsistency with the claimed invention, a variety of combinations, modifications and/or replacements of the directly or indirectly disclosed embodiments are substantially included in the whole disclosure, even though they are not especially mentioned above. The scopes of the claimed invention are defined by the following claims as appended.

1. A noise elimination device for a Class-D audio amplifier, comprising:
a residual signal detector, being configured to detect whether an input signal of the Class-D audio amplifier is residual; and
a multiplexer, being electrically connected with a sigma-delta modulator (SDM) and a pulse width modulator (PWM) of the Class-D audio amplifier and the residual signal detector, and being configured to output zero data into the pulse width modulator when the residual signal detector detects that the input signal of the Class-D audio amplifier is residual.

2. The noise elimination device of claim 1, wherein when an amplitude of the input signal of the Class-D audio amplifier is lower than a first threshold, the residual signal detector detects that the input signal of the Class-D audio amplifier is residual.

3. The noise elimination device of claim 2, wherein when the amplitude of the input signal of the Class-D audio amplifier is higher than a second threshold which is higher than the first threshold, the residual signal detector detects that the input signal of the Class-D audio amplifier is not residual.

4. The noise elimination device of claim 1, wherein when an amplitude of the input signal of the Class-D audio amplifier has been lower than a first threshold for a period of time, the residual signal detector detects that the input signal of the Class-D audio amplifier is residual.

5. The noise elimination device of claim 1, wherein the Class-D audio amplifier is an open-loop Class-D audio amplifier.

6. A Class-D audio amplifier, comprising:
a sigma-delta modulator;
a pulse width modulator; and
a noise elimination device, comprising:
a residual signal detector, being configured to detect whether an input signal of the Class-D audio amplifier is residual; and
a multiplexer, being electrically connected with the sigma-delta modulator, the pulse width modulator and the residual signal detector, and being configured to output zero data into the pulse width modulator when the residual signal detector detects that the input signal of the Class-D audio amplifier is residual.

7. The Class-D audio amplifier of claim 6, further comprising:
a signal processor, being electrically connected with the sigma-delta modulator, and being configured to process the input signal of the Class-D audio amplifier for an input of the sigma-delta modulator; and
a power stage, being electrically connected with the pulse width modulator, and being configured to generate a driving signal for a speaker based on an output of the pulse width modulator.

8. The Class-D audio amplifier of claim 6, wherein when an amplitude of the input signal of the Class-D audio amplifier is lower than a first threshold, the residual signal detector detects that the input signal of the Class-D audio amplifier is residual.

9. The Class-D audio amplifier of claim 8, wherein when the amplitude of the input signal of the Class-D audio amplifier is higher than a second threshold which is higher than the first threshold, the residual signal detector detects that the input signal of the Class-D audio amplifier is not residual.

10. The Class-D audio amplifier of claim 6, wherein when an amplitude of the input signal of the Class-D audio amplifier has been lower than a first threshold for a period of time, the residual signal detector detects that the input signal of the Class-D audio amplifier is residual.

11. The Class-D audio amplifier of claim 6, wherein the Class-D audio amplifier is an open-loop Class-D audio amplifier.
